(19) United States
(12) Patent Application Publication
(10) Pub. No.: US 2004/0021522 A1
(43) Pub. Date: Feb. 5, 2004

(54) Magnetron

(75) Inventors: Jong-Chull Shon, Suwon-City (KR); Boris V. Rayskiy, Suwon-City (KR); Chul Kim, Anyang-City (KR); Hyun-Jun Ha, Suwon-City (KR)

Correspondence Address: STAAS & HALSEY LLP, SUITE 700, 1201 NEW YORK AVENUE, N.W., WASHINGTON, DC, 20005, US

(73) Assignee: Samsung Electronics Co., Ltd., Suwon-City (KR)

(21) Appl. No.: 10/302,993

(22) Filed: Nov. 25, 2002

(30) Foreign Application Priority Data
Aug. 5, 2002 (KR) 2002-46168

(51) Int. Cl. H03B 9/10

(52) U.S. Cl. 331/86

(57) ABSTRACT

A magnetron includes a positive polar cylinder, a plurality of vanes, a filament, upper and lower shields, and upper and lower pole pieces. The vanes are disposed in the positive polar cylinder to constitute a positive polar section along with the positive polar cylinder. The filament is disposed on an axis of the positive polar cylinder to form an activating space together with front end surfaces of the vanes and emit thermions. The upper and lower shields cover a top and bottom of the filament, respectively. The upper and lower pole pieces are spaced apart from the upper and lower shields, respectively, to induce magnetic flux in the activating space. In the present invention, the upper shield has a bottom surface formed to be entirely protruded downwardly, and the lower shield has a top surface formed to be entirely protruded upwardly.

### CROSS-REFERENCE TO RELATED APPLICATIONS

This application claims the benefit of Korean Application No. 2002-46168, filed Aug. 5, 2002, in the Korean Intellectual Property Office, the disclosure of which is incorporated herein by reference.

### BACKGROUND OF THE INVENTION

1. Field of the Invention

The present invention relates generally to a magnetron, and more particularly, to upper and lower shields attached to both end portions of a filament of the magnetron.

2. Description of the Related Art

Generally, a magnetron is constructed to be provided with an anode and a cathode such that thermions are discharged from the cathode and spirally moved to the anode by an electromagnetic force. A spinning electron pole is generated around the cathode by the thermions and current is induced in an oscillation circuit of the anode, so that oscillation is continuously stimulated. An oscillation frequency of the magnetron is generally determined by the oscillation circuit, and has high efficiency and high output power. The magnetron is widely used in home appliances, such as microwave ovens, as well as in industrial applications, such as high-frequency heating apparatuses, particle accelerators and radar systems.

The general construction and operation of the above-described magnetron are briefly described with reference to FIGS. 1 through 3.

As shown in FIG. 1, the magnetron generally includes a positive polar cylinder 101 made of an oxygen free copper pipe or the like, a plurality of vanes 102 disposed in the positive polar cylinder 101, to constitute a positive polar section along with the positive polar cylinder 101 and radially arranged at regular intervals to form a cavity resonator, and an antenna 103 connected to one of the vanes 102 to induce harmonics to an outside. The magnetron also includes a large-diameter strip ring 104 and a small-diameter strip ring 105 disposed on upper and lower portions of the vanes 102, respectively, to alternately and electrically connect the vanes 102 so that the vanes 102 alternately have the same electric potential as shown in FIG. 2.

Rectangular depressions 202 are formed in the vanes 102, respectively, to allow the strip rings 104 and 105 to alternately and electrically connect the vanes 102, and cause each pair of neighboring vanes 102 to be disposed in an inverted manner. According to the above-described construction, each of the pair of neighboring vanes 102 and the positive polar cylinder 101 constitute a certain LC resonant circuit. Additionally, a filament 106 in a form of a coil spring is disposed in an axial center portion of the positive polar cylinder 101, and an activating space 107 is provided between radially inside ends of the vanes 102 and the filament 106. An upper shield 108 and a lower shield 109 are attached to a top and bottom of the filament 106, respectively. A center lead 110 is fixedly welded to a bottom of the upper shield 108 while being passed through a through hole of the lower shield 109 and the filament 106. A side lead 111 is welded to a bottom of the lower shield 109. The center lead 110 and the side lead 111 are connected to terminals of an external power source (not shown), and therefore, forms a closed circuit in the magnetron.

An upper permanent magnet 112 and a lower permanent magnet 113 are provided to apply a magnetic field to the activating space 107 with opposite magnetic poles of the upper and lower permanent magnets 112 and 113 facing each other. An upper pole piece 117 and a lower pole piece 118 are provided to induce rotating magnetic flux generated by the permanent magnets 112 and 113 into the activating space 107.

The above-described elements are enclosed in an upper yoke 114 and a lower yoke 115. Cooling fins 116 connect the positive polar cylinder 101 to the lower yoke 115, and radiate heat generated in the positive polar cylinder 101 to the outside through the lower yoke 115.

According to the above-described construction of the magnetron, when power is applied to the filament 106 from the external power source, the filament 106 is heated by operational current supplied to the filament 106, the thermions are emitted from the filament 106, and a thermion group 301 is produced in the activating space 107 by the emitted thermions as shown in FIG. 3. The thermion group 301 alternately imparts a potential difference to each neighboring pair of the vanes 102 while being in contact with front ends of the vanes 102, being rotated by influence of a magnetic field formed in the activating space 107, and being moved from one state “i” to another state “f.” Accordingly, harmonics corresponding to a rotation speed of the thermion group 301 are generated by oscillation of the LC resonant circuit formed by the vanes 102 and the positive polar cylinder 101, and transmitted to the outside through the antenna 103.

Generally, a frequency is calculated by an equation

$$f = \frac{1}{2 π \sqrt{LC}} ,$$

where L is an inductance and C is a capacitance. Values of the variables of the above equation are determined by geometrical configurations of circuit elements. Thus, the configurations of the vanes constituting part of the LC resonant circuit are principal factors that determine the frequency of harmonics.

Generally, electric and magnetic fields are formed in the activating space. The lines indicated in the activating space 107 of FIG. 4 represent equipotential surfaces. The electric field is always formed perpendicularly to the equipotential surfaces. Further, although not shown in FIG. 4, lines of magnetic force are formed in the activating space 107 by the permanent magnets 112 and 113 respectively arranged in upper and lower portions of the magnetron. In the conventional magnetron, as the thermions generated from the filament 106 which acts as the cathode and used to form the thermion group 301, are applied with a Lorenz force (F=q(E+vB)) under the influences of the electric and magnetic fields in the activating space 107, they move toward the vanes 102. In the above Lorenz force equation, q represents an amount of electric charge, v represents a moving velocity of electric charge, E represents an intensity of the electric field, and B represents an intensity of the magnetic field. Further, the magnetic force always acts perpendicularly to a moving direction of electric charge.

However, there are electric charges applied with the Lorenz force such that thermions which move around upper and lower portions of the filament 106 deviate from the activating space 107, due to the magnetic and electric fields formed in empty spaces between the upper shield 108 and the upper pole piece 117 and between the lower shield 109 and the lower pole piece 118, as shown in FIG. 4 (here, the lower shield and the lower pole piece are omitted in FIG. 4). Therefore, a phenomenon in which the electric charges deviate from the activating space 107 due to the Lorenz force causes an efficiency of the magnetron to decrease. In order to eliminate the phenomenon, there has been used a method of mechanically suppressing the deviation of thermions by forming a geometrical structure of the upper shield 108 (see FIG. 5A) in the shape of a hat, and forming the top surface of the lower shield 109 (see FIG. 5B) to be dented. As shown in FIG. 1, the upper shield 108 is in the shape of a hat, and the lower shield 109 has a dented top surface.

If distribution of the electric field in the activating space 107 is not uniform in the magnetron, electronic beams are unstable and noise is emitted to the outside. In the magnetron using the upper and lower shields 108 and 109 shown in FIGS. 5A and 5B, a distribution of space charges is asymmetrical at portions around the upper and lower shields 108 and 109 in the activating space 107, as shown in FIG. 6. The asymmetry may cause a generation of very high harmonics, moving an axis of vanes upwardly and downwardly.

Further, it is ultimately electric and magnetic fields that apply force of a predetermined direction to thermions. Therefore, a suppression scheme of using a mechanical construction of the upper and lower shields 108 and 109, as shown in FIG. 5, is restrictive. Accordingly, the conventional magnetron is problematic in that it is impossible to fundamentally prevent deviation of thermions.

### SUMMARY OF THE INVENTION

Accordingly, it is an aspect of the present invention to provide upper and lower shields of a magnetron, which electromagnetically prevent the deviation of electric charges rather than mechanically prevent the deviation like a conventional magnetron, by changing shapes of upper and lower shields such that electric field distributions between the upper shield and an upper pole piece and between the lower shield and a lower pole piece are different from those of the conventional magnetron. The upper and lower shields are constructed such that thermion distribution is symmetrical around the upper and lower shields and the symmetrical thermion distribution is realized in an entire activating space, thus reducing noise of a magnetron and improving an efficiency of the magnetron.

Additional aspects and advantages of the invention will be set forth in part in the description which follows and, in part, will be obvious from the description, or may be learned by practice of the invention.

The foregoing and other aspects of the present invention are achieved by providing a magnetron including a positive polar cylinder, a plurality of vanes disposed in the positive polar cylinder, to constitute a positive polar section along with the positive polar cylinder, a filament disposed on an axis of the positive polar cylinder, to form an activating space together with front end surfaces of the vanes and to emit thermions. The magnetron also includes an upper shield to cover a top of the filament, a lower shield to cover a bottom of the filament, and upper and lower pole pieces spaced apart from the upper and lower shields, respectively, to induce magnetic flux in the activating space. The upper shield has a bottom surface formed to be entirely protruded downwardly, and the lower shield has a top surface formed to be entirely protruded upwardly.

### BRIEF DESCRIPTION OF THE DRAWINGS

The above and other aspects and advantages of the invention will become apparent and more appreciated from the following description of the preferred embodiments, taken in conjunction with the accompanying drawings of which:

FIG. 1 is a side section view of a conventional magnetron;

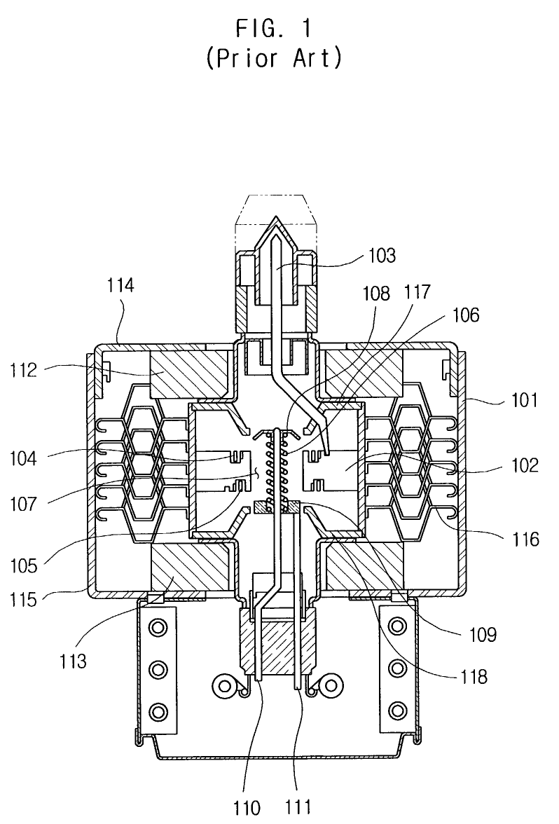

FIG. 2 is a top view showing positive and negative polar sections of the magnetron of FIG. 1;

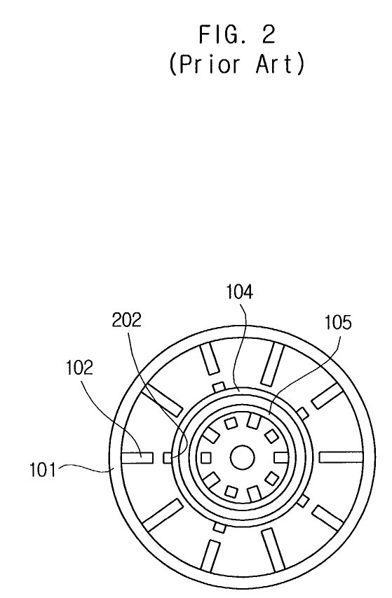

FIG. 3 is a top view showing the positive and negative polar sections of FIG. 2 when the magnetron is in an operating state;

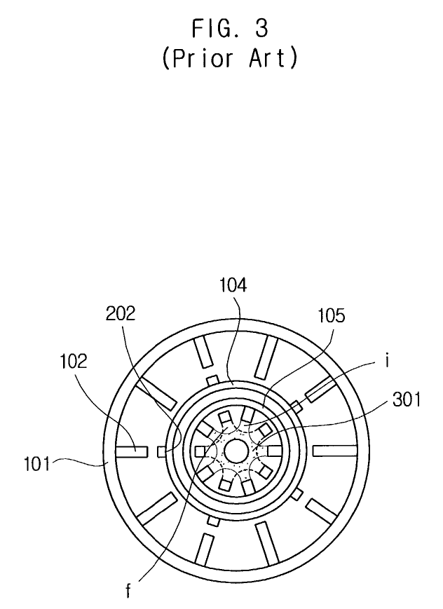

FIG. 4 is a side sectional view showing equipotential surfaces in a conventional activating space;

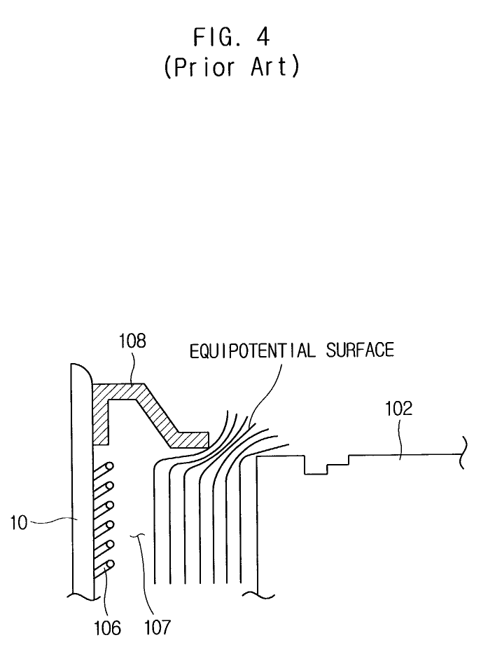

FIGS. 5A and 5B are side sectional views showing conventional upper and lower shields;

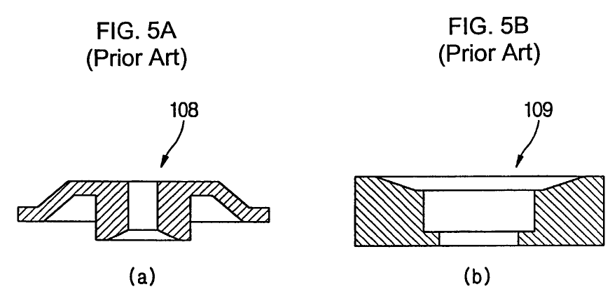

FIG. 6 is a graph showing a distribution of space charge in the conventional activating space;

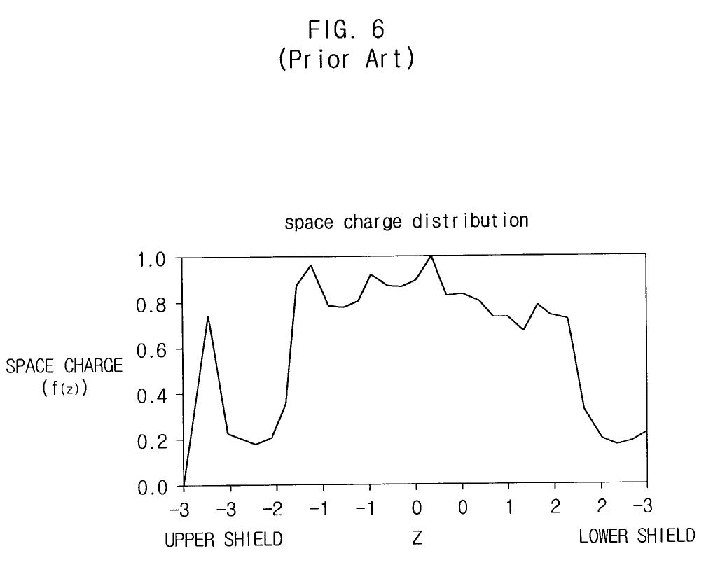

FIG. 7 is a view showing an upper shield, according to an embodiment of the present invention;

FIG. 8 is a view showing a lower shield, according to another embodiment of the present invention; and

FIG. 9 is a graph showing a distribution of space charge in an activating space according to the present invention.

### DETAILED DESCRIPTION OF THE PREFERRED EMBODIMENTS

Reference will now be made in detail to the present preferred embodiments of the present invention, examples of which are illustrated in the accompanying drawings, wherein like reference numerals refer to like elements throughout.

Generally, asymmetry of space charge distribution in an activating space cannot be determined by vanes or a filament in view of its characteristics. This is because the vanes and the filament are arranged to be symmetrical, while the vanes face each other from opposite sides of the filament. In regard to charge distribution in the activating space, a space charge density is determined by geometrical configurations of upper and lower shields arranged on a top and bottom of the filament. Thus, the space charge distribution in the activating space is adjusted by varying shapes of the upper and lower shields. Therefore, the present invention adjusts the space charge density in the activating space by varying the shapes of the upper and lower shields. Accordingly, thermions are prevented from deviating from the activating space by partially adjusting electric and magnetic fields, thereby preventing a force from outside of the activating space from acting on electric charges therein.

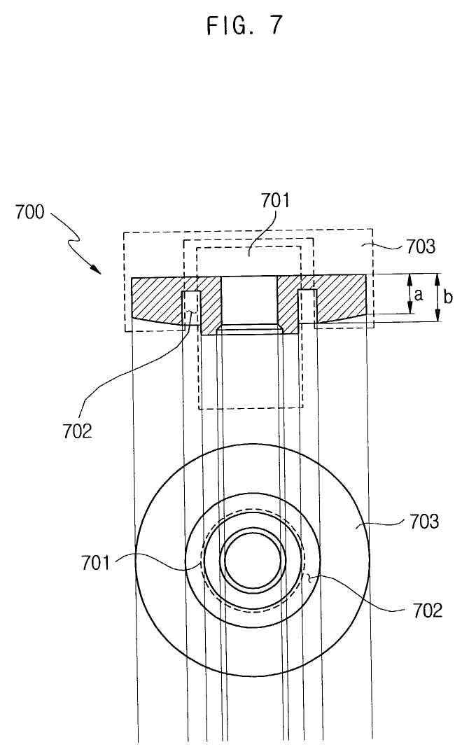

The present invention will be described in detail with reference to FIGS. 7 through 9. For simplicity of description, the same constructions and operations as those of the conventional magnetron may be omitted.

FIG. 7 is a view showing an upper shield 700, according to an embodiment of the present invention. An upper portion of FIG. 7 shows a side sectional view of the upper shield 700, and a lower portion of FIG. 7 shows a bottom view of the upper shield 700 (that is, a surface of the upper shield 700 facing a lower shield).

The upper shield 700 of the present invention includes a center lead attaching piece 701, a circumference part 703, and a filament seating groove 702. The center lead attaching piece 701 is a portion to which a center lead passed through a filament and attached to the upper shield 700, is attached. The circumference part 703 forms a periphery of the upper shield 700. The filament seating groove 702 is formed upwardly from the bottom of the upper shield 700 as a circular groove between the center lead attaching piece 701 and the circumference part 703, so as to allow the filament to be inserted and attached thereto.

A thickness “b” of a side of the filament seating groove 702 of the upper shield 700 is formed to be greater than that of an outer edge “a” of a side of the circumference part 703 of the upper shield 700. A bottom surface of the upper shield 700 is formed to protrude downwardly, without considering the filament seating groove 702 and a hole to accommodate the center lead. That is, a thickness of the circumference part 703 decreases radially from a center portion thereof to the outer edge portion.

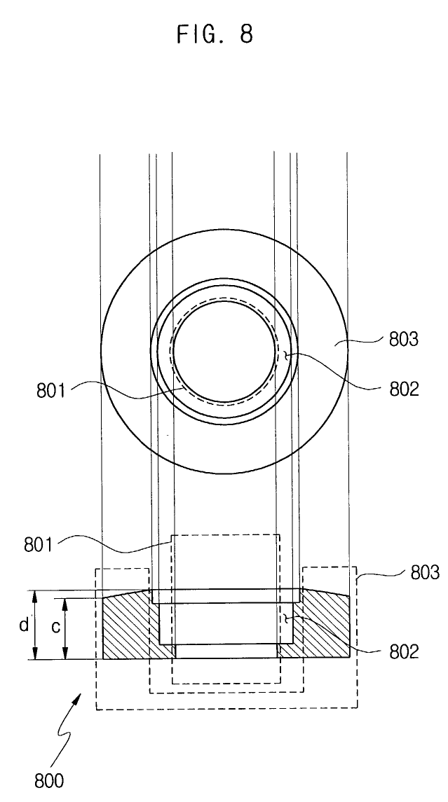

FIG. 8 is a view showing a lower shield 800, according to another embodiment of the present invention. An upper portion of FIG. 8 shows a side sectional view of the lower shield 800, and a lower portion of FIG. 8 shows a bottom view of the lower shield 800 (that is, a surface of the lower shield 800 facing the upper shield 700). The lower shield 800 includes a center lead attaching piece 801, a circumference part 803, and a filament seating depression 802. The center lead attaching piece 801 is a portion to which the center lead passed through the filament and attached to the lower shield 800, is attached. The circumference part 803 forms a periphery of the lower shield 800. The filament seating depression 802 is formed downwardly from a top of the lower shield 800 as a circular groove between the center lead attaching piece 801 and the circumference part 803, so as to allow the filament to be inserted and attached thereto.

A thickness “d” of a side of the filament seating depression 802 of the lower shield 800 is formed to be greater than that of an outer edge “c” of a side of the circumference part of the lower shield 800. A top surface of the lower shield 800 is formed to protrude upwardly, without considering the filament seating depression 802 and a hole to accommodate the center lead. That is, a thickness of the circumference part 803 decreases radially from a center portion thereof to the outer edge portion.

Operations of the magnetron of the present invention employing the upper and lower shields 700 and 800 as described above are described hereinbelow.

If external power is applied to the center lead and a side lead arranged in the magnetron, the filament becomes a cathode to emit thermions, and the vanes and the positive polar cylinder become an anode, thus enabling thermions to move to front end surfaces of the vanes under the influences of electric and magnetic fields. Distributions of electric and magnetic fields in an open space among the upper shield, the vanes and the upper pole piece, and another open space among the lower shield 800, the vanes and the lower pole piece, differ from that of the conventional magnetron. Therefore, in the magnetron of the present invention, an electromagnetic force acting upon an outside of the conventional activating space is greatly reduced, thus preventing thermions from deviating from the activating space.

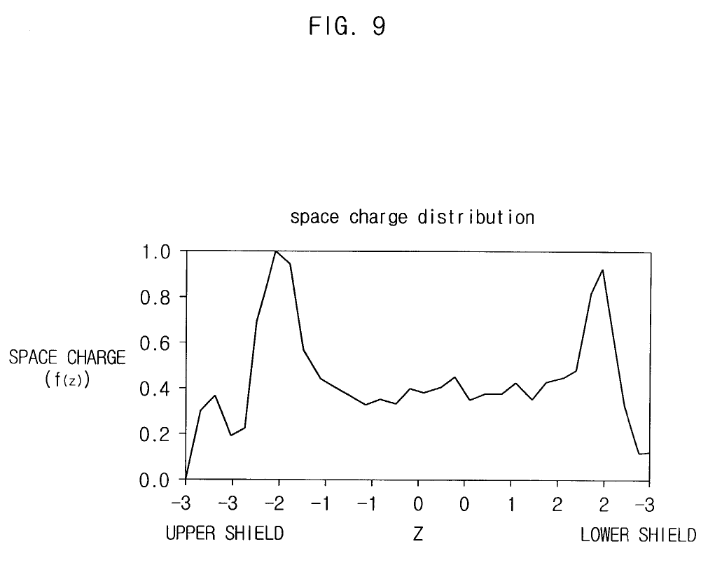

FIG. 9 is a graph showing a distribution of space charge in the activating space of the magnetron of the present invention. Referring to FIG. 9, a vertical axis represents a space charge density, and a horizontal axis represents a range from the top to the bottom of the filament. A center of the filament is set to “0,” and is represented by “Z.” That is, the left portion of the horizontal axis represents a surrounding portion where the upper shield 700 is located and is denoted by a negative (−) sign. Further, a right portion of the horizontal axis represents a surrounding portion where the lower shield 800 is located and is denoted by a positive (+) sign. In reference to the distribution chart, if an activating space is folded in half around the center of the filament at a point “0,” a symmetrical electric charge distribution may be obtained. Thus, it is easily recognized through the graph shown in FIG. 9 that the electric charge distribution in the activating space is almost symmetrical.

In the present invention, the bottom surface of the upper shield is formed to be downwardly protruded. That is, the bottom of a section of the circumference part may form a curved line or a straight line in a radial direction of the circumference part. Further, the top surface of the lower shield is formed to be upwardly protruded. That is, the top of a section of the circumference part may form a curved line or a straight line in a radial direction of the circumference part.

Effects of upper and lower shields are not greatly varied by proper modification thereto. Therefore, those skilled in the art will appreciate that various modifications, additions and substitutions are possible, without departing from the scope and spirit of the invention as disclosed in the accompanying claims.

As described above, the present invention provides a magnetron, which is constructed to have different geometrical shapes of upper and lower shields from those of a conventional magnetron, so the electric and magnetic fields around the upper and lower shields are changed, thus preventing thermions from deviating from an activating space to improve the efficiency of the magnetron, and forming the distribution of thermions in the activating space to be symmetrical to reduce noise and oscillate stable frequencies of the magnetron. As a result, the efficiency of the magnetron is entirely improved.

Although a few preferred embodiments of the present invention have been shown and described, it would be appreciated by those skilled in the art that changes may be made in these embodiments without departing from the principles and spirit of the invention, the scope of which is defined in the claims and their equivalents.

What is claimed is:

1. A magnetron, comprising:
a positive polar cylinder;
a plurality of vanes disposed in the positive polar cylinder, to constitute a positive polar section along with the positive polar cylinder;
a filament disposed on an axis of the positive polar cylinder, to form an activating space together with front end surfaces of the vanes, and to emit thermions;
an upper shield to cover a top of the filament;
a lower shield to cover a bottom of the filament; and
upper and lower pole pieces spaced apart from the upper and lower shields, respectively, to induce magnetic flux in the activating space,
wherein the upper shield has a bottom surface formed to be entirely protruded downwardly.

2. The magnetron according to claim 1, wherein the lower shield has a top surface formed to be entirely protruded upwardly.

3. A magnetron, comprising:
a positive polar cylinder;
a plurality of vanes disposed in the positive polar cylinder, to constitute a positive polar section along with the positive polar cylinder;
a filament disposed on an axis of the positive polar cylinder, to form an activating space together with front end surfaces of the vanes, and to emit thermions;
an upper shield to cover a top of the filament;
a lower shield to cover a bottom of the filament; and
upper and lower pole pieces spaced apart from the upper and lower shields, respectively, to induce magnetic flux in the activating space,
wherein the lower shield has a top surface formed to be entirely protruded upwardly.

4. The magnetron according to claim 3, wherein the upper shield has a bottom surface formed to be entirely protruded downwardly.

5. A magnetron having a filament, comprising:
upper and lower shields to cover a top and a bottom of the filament in the magnetron; and
upper and lower pole pieces spaced apart from the upper and lower shields, respectively, to induce magnetic flux in an activating space of the magnetron,
wherein the upper shield has a bottom surface formed to be entirely protruded downwardly.

6. The magnetron according to claim 5, wherein the upper shield comprises:
a center lead attaching device to allow a center lead to pass through the filament of the magnetron and attach to the upper shield;
a circumference part to form a periphery of the upper shield; and
a filament seating groove formed upwardly from a bottom of the upper shield as a circular groove between the center lead attaching device and the circumference part, to allow the filament to be inserted and attached thereto.

7. The magnetron according to claim 6, wherein a thickness of a side of the filament seating groove is formed to be greater than an outer edge of a side of the circumference part.

8. The magnetron according to claim 6, wherein a thickness of the circumference part decreases radially from a center portion thereof to an outer edge.

9. A magnetron having a filament, comprising:
upper and lower shields to cover a top and a bottom of the filament in the magnetron; and
upper and lower pole pieces spaced apart from the upper and lower shields, respectively, to induce magnetic flux in an activating space of the magnetron,
wherein the lower shield has a top surface formed to be entirely protruded upwardly.

10. The magnetron according to claim 9, wherein the lower shield comprises:
a center lead attaching device to allow a center lead to pass through the filament of the magnetron and attach to the lower shield;
a circumference part to form a periphery of the lower shield; and
a filament seating depression formed downwardly from a top of the lower shield as a circular groove between the center lead attaching device and the circumference part, to allow the filament to be inserted and attached thereto.

11. The magnetron according to claim 10, wherein a thickness of a side of the filament seating depression is formed to be greater than an outer edge of a side of the circumference part.

12. The magnetron according to claim 10, wherein a thickness of the circumference part decreases radially from a center portion thereof to an outer edge.

13. A magnetron for microwave ovens, comprising:
upper and lower shields to cover a top and a bottom of a filament in the magnetron; and
upper and lower pole pieces spaced apart from the upper and lower shields, respectively, to induce magnetic flux into an activating space provided therebetween, wherein,
the upper shield has a bottom surface formed to be entirely protruded downwardly and the lower shield has a top surface formed to be entirely protruded upwardly to change electric and magnetic fields in the activating space, thereby preventing thermions emitted by the filament from escaping the activating space.

14. A magnetron having a filament, comprising:
shields to cover a top and a bottom of the filament in the magnetron; and
upper and lower pole pieces spaced apart from the shields, respectively, to induce magnetic flux in an activating space of the magnetron,
wherein at least one of the shields has a bottom surface formed to be entirely protruded downwardly.

15. A magnetron having a filament, comprising:
shields to cover a top and a bottom of the filament in the magnetron; and
upper and lower pole pieces spaced apart from the shields, respectively, to induce magnetic flux in an activating space of the magnetron,
wherein at least one of the shields has a top surface formed to be entirely protruded upwardly.

16. A magnetron for microwave ovens, comprising:
shields to cover a top and a bottom of a filament in the magnetron; and
upper and lower pole pieces spaced apart from the shields, respectively, to induce magnetic flux into an activating space provided therebetween, wherein,
at least one of the shields has a bottom surface formed to be entirely protruded downwardly and another one of the shields opposite the one shield has a top surface formed to be entirely protruded upwardly to change electric and magnetic fields in the activating space, thereby preventing thermions emitted by the filament from escaping the activating space.
